(19) United States
(12) Patent Application Publication
(10) Pub. No.: US 2025/0292824 A1
(43) Pub. Date: Sep. 18, 2025

(54) SEMICONDUCTOR DEVICE

(71) Applicant: Samsung Electronics Co., Ltd., Suwon-si (KR)

(72) Inventors: Jungmin You, Suwon-si (KR); Eunae Lee, Suwon-si (KR); Sunghye Cho, Suwon-si (KR); Kyomin Sohn, Suwon-si (KR); Kijun Lee, Suwon-si (KR); Myungkyu Lee, Suwon-si (KR)

(21) Appl. No.: 18/897,025

(22) Filed: Sep. 26, 2024

(30) Foreign Application Priority Data
Mar. 15, 2024 (KR) 10-2024-0036589

(51) Int. Cl. G11C 11/4091; G11C 11/406; G11C 11/408

(52) U.S. Cl. CPC G11C 11/4091; G11C 11/40618; G11C 11/4087

(57) ABSTRACT

A semiconductor device includes a cell area in which a plurality of memory banks are disposed, with each memory bank including a respective memory cell array having therein a plurality of memory cells, a row decoder connected to the memory cell array, and a sense amplifier circuit. A peripheral circuit area is provided, which includes a logic circuit controlling the plurality of memory banks. The logic circuit includes at least one queue configured to store a row hammer address for at least one of the plurality of memory banks, and controls: (i) a target memory bank to execute a row hammer refresh operation in the target memory bank indicated by a row hammer address when the row hammer address stored in the queue is present, and (ii) the plurality of memory banks to execute a normal refresh operation when the row hammer address stored in the queue is not present.

### REFERENCE TO PRIORITY APPLICATION

This application claims priority under 35 USC 119(a) to Korean Patent Application No. 10-2024-0036589, filed Mar. 15, 2024, the disclosure of which is hereby incorporated herein by reference.

### BACKGROUND

The present inventive concept relates to integrated circuit memory devices and methods of operating same.

Integrated circuit memory devices contain semiconductor devices that may store data and read the stored data. A memory device may include a memory cell array in which memory cells storing data are disposed, a row decoder connected to the memory cells through word lines, a sense amplifier connected to the memory cells through bit lines, and the like. To prevent loss of data written into memory cells, an integrated circuit device may perform a refresh operation to reprogram data written in memory cells. In addition, a refresh operation may also be executed to prevent data fluctuations in memory cells connected to adjacent word lines due to a row hammer phenomenon in which access to a specific word line occurs intensively among word lines.

### SUMMARY

Example embodiments provide an integrated circuit memory device in which a row hammer refresh operation is utilized to prevent data fluctuation due to a row hammer phenomenon, and a normal refresh operation is utilized to prevent data loss in memory cells may be dynamically scheduled according to situations, thereby optimizing power consumption due to refresh operation and increasing defense against a row hammer phenomenon.

According to example embodiments, an integrated circuit device includes a cell area in which a plurality of memory banks are disposed, with each of the plurality of memory banks including a memory cell array including a plurality of memory cells, a row decoder connected to the memory cell array through a plurality of word lines, and a sense amplifier circuit connected to the memory cell array through a plurality of bit lines, and a peripheral circuit area in which a logic circuit controlling the plurality of memory banks is disposed. The logic circuit includes at least one queue for storing a row hammer address for at least one of the plurality of memory banks. The logic circuit controls a target memory bank to execute a row hammer refresh operation in the target memory bank indicated by a row hammer address when the row hammer address stored in the queue is present, and controls the plurality of memory banks to execute a normal refresh operation when the row hammer address stored in the queue is not present.

According to other example embodiments, an integrated circuit device includes a cell area in which a plurality of memory banks are disposed, with each of the plurality of memory banks including a memory cell array including a plurality of memory cells, a row decoder connected to the memory cell array through a plurality of word lines, and a sense amplifier circuit connected to the memory cell array through a plurality of bit lines, and a peripheral circuit area configured to execute, for each of the plurality of memory banks, a row hammer refresh operation of detecting an aggressor word line among the plurality of word lines and refreshing target memory cells connected to target word lines adjacent to the aggressor word line, a first normal refresh operation of activating the plurality of word lines by an n number at a time, and a second normal refresh operation of activating the plurality of word lines by an m number at a time, with m being greater than n. The peripheral circuit area includes a counter for storing a number of execution times of the row hammer refresh operation. When the number of execution times stored in the counter is greater than 0, the peripheral circuit area executes the second normal refresh operation until the number of the execution times stored in the counter becomes 0.

According to further embodiments, an integrated circuit device includes a cell area in which a plurality of memory banks are disposed, with each of the plurality of memory banks including a plurality of memory cells connected to a plurality of word lines and a plurality of bit lines, and a peripheral circuit area in which a logic circuit is provided. The logic circuit executes, for each of the plurality of memory banks, a row hammer refresh operation by detecting an aggressor word line among the plurality of word lines and refreshing memory cells connected to victim word lines adjacent to the aggressor word line, and a normal refresh operation by refreshing memory cells connected to at least one selected word line among the plurality of word lines. The peripheral circuit area includes a queue in which a row hammer address indicating at least one of the aggressor word line and the victim word lines is stored, and a counter in which a number of executions of the row hammer refresh operation is stored. The logic circuit executes one of the row hammer refresh operation and the normal refresh operation at each refresh timing coming at a predetermined refresh period based on at least one of a state of the queue and a value stored in the counter.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a block diagram schematically illustrating a system including an integrated circuit device according to example embodiments;

FIGS. 2 and 3 are diagrams schematically illustrating a structure of an integrated circuit device according to example embodiments;

FIGS. 4 and 5 are schematic diagrams of an integrated circuit device according to example embodiments;

FIG. 6 is a flowchart illustrating operations of an integrated circuit device according to example embodiments;

FIGS. 7 to 9 are diagrams illustrating a refresh operation of an integrated circuit device according to example embodiments;

FIGS. 10 to 13 are diagrams illustrating the operation of an integrated circuit device according to example embodiments;

FIG. 14 is a diagram illustrating the operation of an integrated circuit device according to example embodiments;

FIG. 15 is a flowchart illustrating the operation of an integrated circuit device according to example embodiments;

FIG. 16 is a diagram illustrating the operation of an integrated circuit device according to example embodiments;

FIG. 17 is a diagram illustrating the operation of an integrated circuit device according to example embodiments; and

FIG. 18 is a diagram illustrating the operation of an integrated circuit device according to example embodiments.

### DETAILED DESCRIPTION

Hereinafter, example embodiments will be described with reference to the accompanying drawings.

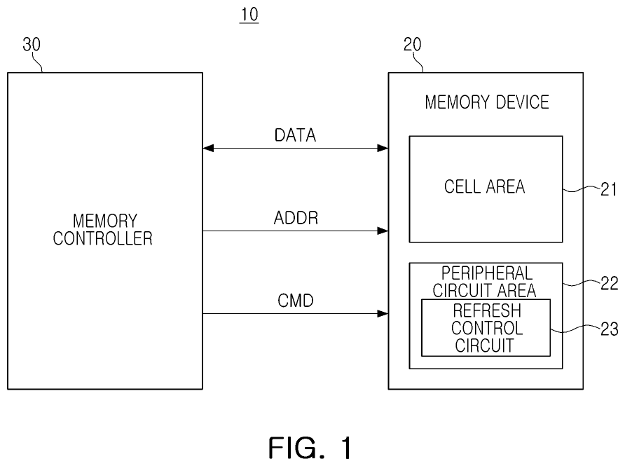

FIG. 1 is a block diagram schematically illustrating a system including an integrated circuit device according to example embodiments. Referring to FIG. 1, a system 10 may include a memory device 20 and a memory controller 30. In an example embodiment illustrated in FIG. 1, an integrated circuit device according to example embodiments may be provided as a memory device 20, and the memory device 20 and the memory controller 30 may be connected through a memory interface to exchange signals with each other.

As will be understood by those skilled in the art, the memory device 20 may operate based on signals received from the memory controller 30. For example, as illustrated, the memory controller 30 may transmit a command signal CMD and an address signal ADDR to the memory device 20; and, the memory device 20 may execute control operations such as a write operation, a read operation, and a refresh operation based on the command signal CMD. The control operation is executed on at least one target memory cell among the plurality of memory cells included in the memory device 20, and the target memory cell may be designated by the address signal ADDR. The memory controller 30 may transmit a data signal DATA to be recorded in the memory device 20 to the memory device 20, and may receive data stored in the memory device 20 as a data signal DATA from the memory device 20.

The memory device 20 may include a cell area 21 and a peripheral circuit area 22. A plurality of memory cells storing data are arranged in the cell area 21, and a logic circuit for controlling the cell area 21, an input/output circuit for exchanging signals with the memory controller 30, and a refresh control circuit 23 for controlling the refresh operation may be disposed in the peripheral circuit area 22. For example, each of the memory cells disposed in the cell area 21 may include a cell capacitor capable of charging an electric charge, and data may be written to the memory cell by charging and discharging the cell capacitor. Nonetheless, as time passes after data is written to a memory cell, the data may be lost due to charge leakage from the cell capacitor. To prevent this, a refresh operation to overwrite the data may be executed in the memory device 20.

In the cell area 21, a plurality of memory cells may be connected to a row decoder through a plurality of word lines (WL) and a sense amplifier circuit through a plurality of bit lines (BL). When a specific word line is intensively selected among a plurality of word lines and a control operation such as a write operation or a read operation is executed, the data of memory cells connected to other adjacent word lines may change during the process of activating the word line. This phenomenon may, in some instances, be known as a Row Hammer phenomenon. When a row hammer phenomenon occurs, the word line that is intensively selected as the execution target of the control operation may be defined as the aggressor word line, and other word lines adjacent to the aggressor word line may be defined as the victim word lines. Considering the tendency for the density of memory cells disposed in the cell area 21 to increase and the spacing between word lines to decrease, there is a need to minimize data fluctuations due to the row hammer phenomenon.

For example, in a normal refresh operation in a DRAM-type integrated circuit memory device, which may be executed independently of the row hammer phenomenon, each of a plurality of word lines may be activated and data in memory cells connected to the activated word line may be rewritten. On the other hand, in the row hammer refresh operation to prevent data fluctuations occurring in memory cells connected to the victim word line due to the row hammer, the victim word line may be specified as the target word line, and data in memory cells connected to the victim word line may be written again to increase data reliability.

When executing a row hammer refresh operation, a normal refresh operation may have to be skipped. Thus, if the row hammer refresh operation is executed too frequently, data loss may occur in memory cells connected to word lines unrelated to the row hammer as the number of skips in the normal refresh operations accumulates. Alternatively, if the number of executions of the row hammer refresh operation is excessively limited, data fluctuations due to the row hammer phenomenon may occur in memory cells connected to a victim word line(s). As such, if the row hammer refresh operation and the normal refresh operation are not appropriately scheduled and regulated, the reliability of the data stored in the cell area 21 and the performance of the memory device 20 may deteriorate.

In some example embodiments, the row hammer address, which is the address of the aggressor word line that causes the row hammer, is stored in a separate queue included in the peripheral circuit area 22, and a row hammer refresh operation may be executed under the condition that a row hammer address stored in the queue is present. Additionally, when the row hammer refresh operation is continuously executed in bursts, the number of consecutive executions of the row hammer refresh operation may be stored in a counter. When the number stored in the counter reaches a predetermined reference number, a normal refresh operation is executed regardless of whether the row hammer address stored in the queue is present, thereby preventing data loss that may occur due to excessive skipping of the normal refresh operation.

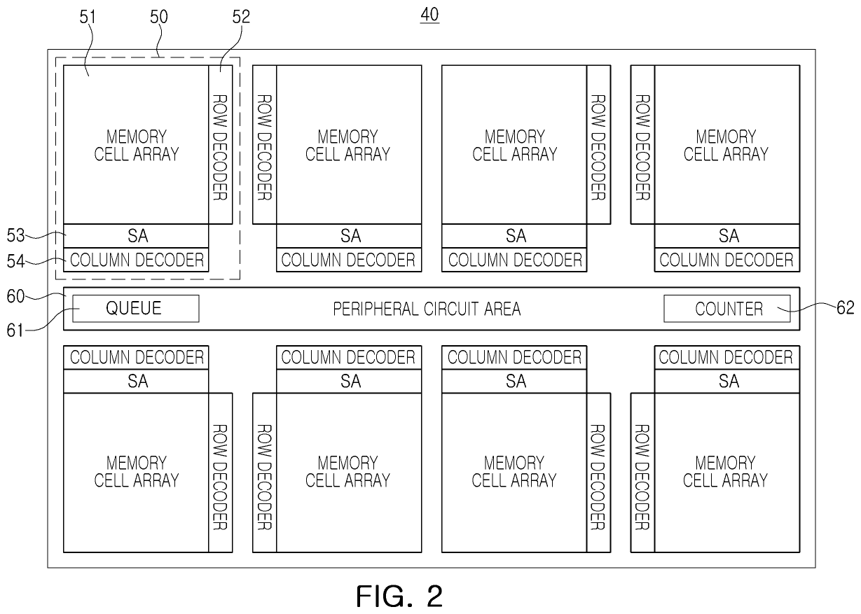

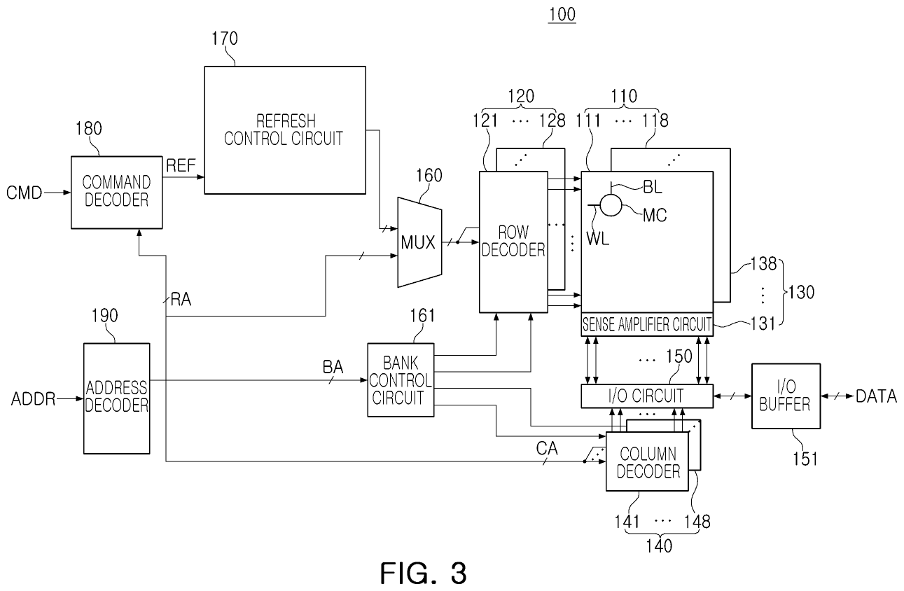

FIGS. 2 and 3 are diagrams schematically illustrating the structure of an integrated circuit device according to example embodiments. First, referring to FIG. 2, the integrated circuit device 40 according to example embodiments may include a cell area in which a plurality of memory banks 50 are disposed, a peripheral circuit area 60, and the like. Each of the plurality of memory banks 50 may include a memory cell array 51, a row decoder 52, a sense amplifier circuit 53, and a column decoder 54. A plurality of memory cells included in the memory cell array 51 may be connected to the row decoder 52 through a plurality of word lines and to the sense amplifier circuit 53 through a plurality of bit lines. On the other hand, in an example embodiment illustrated in FIG. 2, eight memory banks 50 are illustrated as being included in the integrated circuit device 40, but the number of memory banks 50 may vary depending on example embodiments.

In the peripheral circuit area 60, a logic circuit that controls the plurality of memory banks 50, an input/output circuit that exchanges signals with another external device, for example, a memory controller, and the like may be disposed. For example, the peripheral circuit area 60 may control the write operation, read operation, refresh operation, and the like of each of the plurality of memory banks 50 based on the command signal and address signal received from the memory controller.

Referring to FIG. 2, a queue 61 and a counter 62 may be disposed in the peripheral circuit area 60. The queue 61 is a storage space implemented with flip-flops, latches, buffer circuits, a Static Random Access Memory (SRAM), or the like, and may operate in a first-in-first-out (FIFO) method. For example, when a row hammer occurs in at least one of the plurality of memory banks 50, the address of the aggressor word line that caused the row hammer may be stored in the queue 61 as a row hammer address.

The counter 62 may store the number of times the row hammer refresh operation is executed in the plurality of memory banks 50 in response to the row hammer. Depending on example embodiments, the queue 61 and/or the counter 62 may be provided in the peripheral circuit area 60 as many as the number of memory banks 50, to correspond to the plurality of memory banks 50. For example, eight counters 62 corresponding to the eight memory banks 50 may be included in the peripheral circuit area 60, and in the peripheral circuit area 60, each of the counters 62 may be disposed in a position close to the corresponding memory bank 50.

The peripheral circuit area 60 may control the refresh operation of each of the plurality of memory banks 50 based on the values stored in the queue 61 and the counter 62. For example, if there is a row hammer address stored in queue 61, the peripheral circuit area 60 may identify the target memory bank indicated by the row hammer address among the plurality of memory banks 50 and control the target memory bank to execute a row hammer refresh operation. On the other hand, under the condition that there is no row hammer address stored in the queue 61, the peripheral circuit area 60 may control the plurality of memory banks 50 to execute a normal refresh operation at the refresh timing.

For example, the row hammer refresh operation may include reprogramming data for memory cells connected to each of a pair of victim word lines adjacent to the aggressor word line indicated by the row hammer address. In the row hammer refresh operation, the data of memory cells connected to the first victim word line is read and reprogrammed at the first refresh timing, and data from memory cells connected to the second victim word line may be read and reprogrammed at the second refresh timing after the first refresh timing.

The peripheral circuit area 60 may schedule the row hammer refresh operation and the normal refresh operation with reference to the value stored in the counter 62. In example embodiments, the value stored in the counter 62 may correspond to the number of times the row hammer refresh operation is continuously executed in each of the plurality of memory banks 50. For example, if the row hammer refresh operation is executed three times in a row in one memory bank 50, the counter 62 may store the count value for the one memory bank 50 as 3.

To execute the row hammer refresh operation, it is necessary to sacrifice the refresh timing at which the normal refresh operation is executed. If only the row hammer refresh operation is executed excessively, the data retention characteristics of memory cells connected to word lines other than the victim word lines may deteriorate. Therefore, in example embodiments, when the value stored in the counter 62 reaches a predetermined reference value, regardless of whether the row hammer address is stored in the queue 61, a normal refresh operation may be executed in the corresponding memory bank 50. In this manner, by dynamically scheduling the row hammer refresh operation and the normal refresh operation, degradation of retention characteristics of data stored in the plurality of memory banks 50 may be effectively prevented.

Next, referring to FIG. 3, the memory device 100 may include memory cell arrays 111 to 118 (110), row decoders 121 to 128 (120), sense amplifier circuits 131 to 138 (130), column decoders 141 to 148 (140), an input/output (I/O) circuit 150, an I/O buffer 151, a refresh control circuit 170, a command decoder 180, an address decoder 190, and the like. The memory cell arrays 111 to 118 (110), the row decoders 121 to 128 (120), the sense amplifier circuits 131 to 138 (130), and the column decoders 141 to 148 (140) may provide a plurality of memory banks.

The memory cell array 110 includes a plurality of memory cells MC, and each of the plurality of memory cells MC may be connected to the row decoder 120 through a word line WL and may be connected to the sense amplifier circuit 130 through a bit line BL. The command decoder 180 may receive a command signal CMD from an external memory controller, and the like, and control a plurality of memory banks based thereon. For example, when the command signal CMD includes a refresh command REF, the command decoder 180 may decode the command signal CMD to generate a refresh command REF.

The address decoder 190 may receive an address signal ADDR from a memory controller, and the like. The address decoder 190 decodes the address signal ADDR, and may generate a memory bank address BA indicating the target memory bank among the plurality of memory banks, a row address RA indicating a target word line among a plurality of word lines WL included in the target memory bank, and a column address CA indicating the target bit line among the plurality of bit lines BL included in the target memory bank. The row address RA may be provided to the refresh control circuit 170, or may be provided to the row decoder 120 through the multiplexer 160. The column address CA may be provided to the column decoder 140, and the memory bank address BA may be provided to the memory bank control circuit 161.

The refresh control circuit 170 may output a refresh row address REF_RA indicating a target word line on which to execute a refresh operation in response to the refresh command REF. In an example embodiment illustrated in FIG. 3, the multiplexer 160 may select one of the row address RA and the refresh row address REF_RA and transmit it to the row decoder 120. The row decoder 120 may activate a target word line among a plurality of word lines WL included in the target memory bank by referring to the row address RA or refresh row address REF_RA output by the multiplexer 160.

The column decoder 140 may select a target bit line from the plurality of bit lines BL based on the column address CA. The column decoder 140 may activate a sense amplifier corresponding to the column address CA among the sense amplifiers included in the sense amplifier circuit 130 through the I/O circuit 150. The I/O circuit 150 gates input/output data and may include a data latch for storing data read from the memory cell array 110 and a write driver for writing data to the memory cell array 110. The sense amplifier may read data from memory cells connected to the target word line and target bit line in the memory cell array 110, and store it in the data latch of the I/O circuit 150.

In example embodiments, data acquired by the sense amplifier from the memory cell array 110 through a read operation may be output as a data signal DATA through the I/O buffer 151 and provided to the memory controller. Data to be stored in the memory cell array is received by the memory controller as a data signal DATA and provided to the I/O buffer 151, and data provided to the I/O buffer 151 may be provided to the I/O circuit 150.

The refresh control circuit 170 may transmit a refresh row address REF_RA to execute a refresh operation to the multiplexer 160 in response to the refresh command REF. When the multiplexer 160 selects the refresh row address REF_RA, the row decoder 120 may activate the word line on which the refresh operation is to be executed. For example, the refresh control circuit 170 may determine the address of the aggressor word line that generated the row hammer by referring to the row hammer address stored in a separate queue. The refresh control circuit 170 may determine the address of the victim word line based on the address of the aggressor word line and generate a refresh row address REF_RA. Accordingly, the victim word line is activated as the target word line by the row decoder 120 and the row hammer refresh operation may be executed.

On the other hand, if there is no row hammer address stored in a separate queue, the refresh control circuit 170 may generate a refresh row address REF_RA including the address of the target word line on which the normal refresh operation is to be executed. Accordingly, the target word line is activated by the row decoder 120, and a normal refresh operation may be executed.

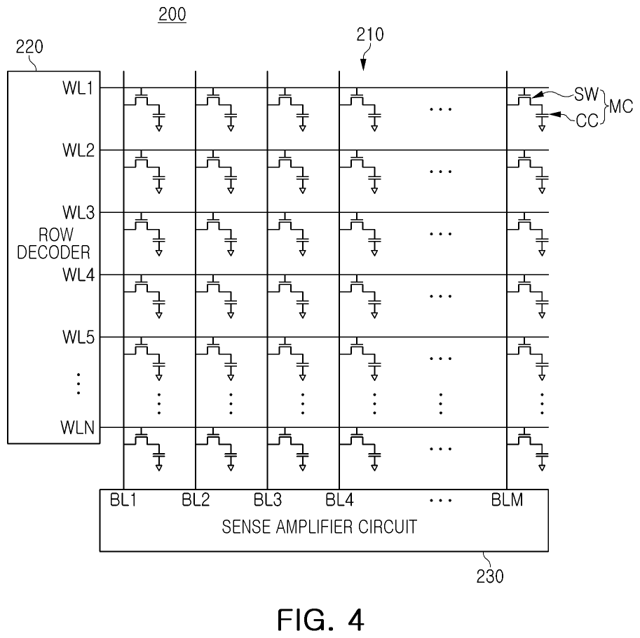

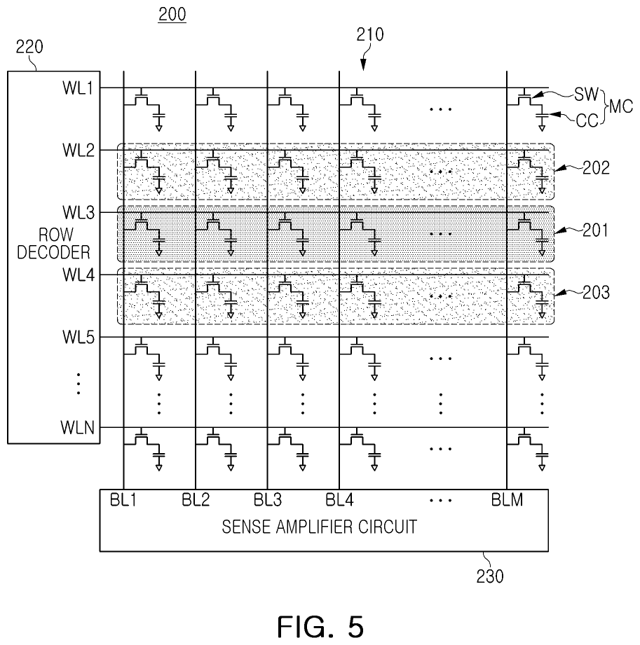

FIGS. 4 and 5 are schematic diagrams of an integrated circuit device according to example embodiments. FIGS. 4 and 5 may be a diagram schematically illustrating the memory cell array 210, the row decoder 220, the sense amplifier circuit 230, and the like included in the integrated circuit device 200 according to example embodiments. Referring to FIGS. 4 and 5, the memory cell array 210 may be connected to the row decoder 220 through a plurality of word lines WL1 to WLN and may be connected to the sense amplifier circuit 230 through a plurality of bit lines BL1 to BLM.

A plurality of word lines WL1 to WLN and a plurality of bit lines BL1 to BLM may be connected to a plurality of memory cells MC. Each of the plurality of memory cells MC may include a switch element SW and a cell capacitor CC. The gate of the switch element SW may be connected to one of the plurality of word lines WL1 to WLN. Therefore, when the selected word line among the plurality of word lines WL1 to WLN is activated and the switch element SW is turned on, a read operation that reads the charge charged in the cell capacitor CC or a write operation that charges (or removes) the charge in the cell capacitor CC may be executed through a selected bit line among the plurality of bit lines BL1 to BLM.

When the row decoder 220 repeatedly selects and activates a specific word line among a plurality of word lines WL1 to WLN, a row hammer phenomenon may occur in which data in memory cells connected to other adjacent word lines is unintentionally changed. Referring to FIG. 5, as the row decoder 220 repeatedly selects and activates the third word line WL3, data in memory cells connected to each of the second word line WL2 and the fourth word line WL4 adjacent to the third word line WL3 may change (and be corrupted by the row hammer phenomenon). In an example embodiment illustrated in FIG. 5, the third word line WL3 may be defined as the aggressor word line 201, and the second word line WL2 and fourth word line WL4 (and possibly a first word line and fifth word line) may be defined as the victim word lines 202 and 203. This row hammer phenomenon may become more severe due to increased integration of the integrated circuit device 200.

To prevent data fluctuation of the victim word lines 202 and 203 due to the row hammer phenomenon, a row hammer refresh operation may be executed at the refresh timing. Unlike the normal refresh operation, which activates word lines WL1 to WLN in order and overwrites/restores data in memory cells MC, in the row hammer refresh operation, the victim word lines 202 and 203 may be specified and data may be overwritten/restored in the memory cells MC connected to the victim word lines 202 and 203 (in order to thwart a row hammer attack).

However, if a row hammer refresh operation is repeatedly executed excessively, a normal refresh operation may not be executed at a normal frequency, and data loss may occur in memory cells MC connected to word lines other than the victim word lines 202 and 203. In example embodiments, the normal refresh operation and the row hammer refresh operation may be dynamically scheduled based on whether a row hammer phenomenon has occurred and the number of skips of the normal refresh operations. Thus, in addition to preventing data fluctuation in the memory cells MC connected to the victim word lines 202 and 203, data loss may also be effectively prevented in memory cells MC connected to word lines other than the victim word lines 202 and 203.

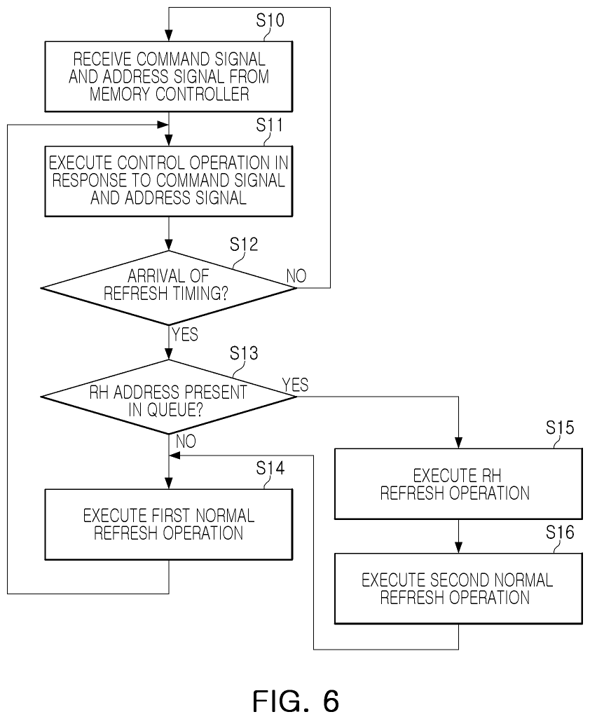

FIG. 6 is a flowchart illustrating the operation of an integrated circuit device according to example embodiments. Referring to FIG. 6, the operation of an integrated circuit device according to example embodiments may begin with the integrated circuit device receiving a command signal and an address signal from a memory controller (S10). The integrated circuit device may be a memory device storing data, and may execute control operations according to command signals and address signals (S11). The control operation may include a write operation to save data, a read operation to output the stored data to the memory controller, and a refresh operation to rewrite/restore the stored data.

While executing the control operation, the logic circuit of the integrated circuit device may determine whether the refresh timing has arrived (S12). For example, when a refresh command is received from a memory controller, the logic circuit of the integrated circuit device may determine that the refresh timing has arrived and perform a refresh operation. If it is determined that the refresh timing has not arrived, the logic circuit of the integrated circuit device may process control operations according to the command signal and address signal received from the memory controller (S10-S11).

When it is determined that the refresh timing has arrived, the logic circuit may determine whether a row hammer address is present in a queue arranged in the peripheral circuit area (S13). The row hammer address may include at least one of the address of the aggressor word line that generates the row hammer phenomenon and the address of the victim word line adjacent to the aggressor word line.

As a result of the determination in operation S13, if the row hammer address is not present in the queue, the logic circuit may perform the first normal refresh operation (S14). In the first normal refresh operation, the logic circuit of the integrated circuit device may activate at least one of a plurality of word lines by referring to an address received along with a refresh command or an address determined to be the target of the next refresh operation within the integrated circuit device. A refresh operation may be executed in which data from memory cells connected to the activated word line is read and rewritten. In example embodiments, in the first normal refresh operation, n word lines (n is a natural number of 2 or more) may be activated simultaneously.

On the other hand, if the row hammer address is present in the queue as a result of the determination in operation S13, the logic circuit of the integrated circuit device may perform the row hammer RH refresh operation (S15). In the row hammer refresh operation, the logic circuit may refer to the row hammer address stored in the queue and specify the victim word line adjacent to the aggressor word line as the target word line. For example, the logic circuit of the integrated circuit device may specify a pair of victim word lines adjacent to the aggressor word line as target word lines.

In example embodiments, target word lines may be activated one at a time in a row hammer refresh operation. For example, the logic circuit of the integrated circuit device may activate a first victim word line adjacent to the aggressor word line at the first refresh timing and overwrite data in memory cells connected to the first victim word line. At the second refresh timing immediately after the first refresh timing, the logic circuit of the integrated circuit device may activate a second victim word line adjacent to the aggressor word line and overwrite/restore data in memory cells connected to the second victim word line.

When the row hammer refresh operation is completed and the next refresh timing arrives, the logic circuit of the integrated circuit device may perform the second normal refresh operation (S16). The second normal refresh operation may be similar to the first normal refresh operation. However, the number of word lines activated at one time in the second normal refresh operation may be greater than the number of word lines activated at one time in the first normal refresh operation.

For example, the logic circuit may activate m word lines (m is a natural number greater than n) at the same time in the second normal refresh operation. In this manner, by simultaneously activating a greater number of word lines in the second normal refresh operation than in the first normal refresh operation, the first normal refresh operation that is not executed at the first refresh timing and the second refresh timing may be compensated.

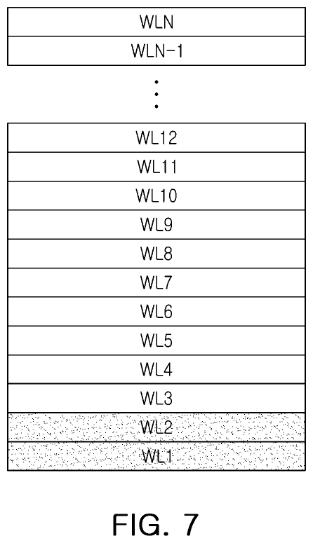

FIGS. 7 to 9 are diagrams provided to explain a refresh operation of an integrated circuit device according to example embodiments. FIG. 7 may be a diagram for explaining the first normal refresh operation. Referring to FIG. 7, a memory cell array included in one memory bank includes N word lines WL1 to WLN, and a plurality of memory cells may be connected to each of the word lines WL1 to WLN. In the first normal refresh operation according to the example embodiment illustrated in FIG. 7, two word lines may be activated simultaneously. The peripheral circuit area of the integrated circuit device may overwrite data in memory cells connected to the two activated word lines. In FIG. 7, two word lines adjacent to each other are illustrated to be activated at the same time. Alternatively, two word lines that are not consecutive to each other may be activated at the same time.

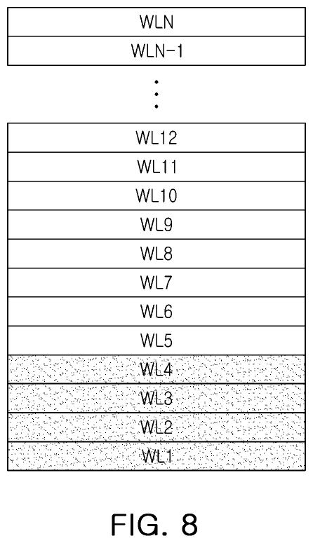

FIG. 8 may be a diagram for explaining a second normal refresh operation. In the second normal refresh operation according to the example embodiment illustrated in FIG. 8, four word lines may be activated simultaneously. The peripheral circuit area of the integrated circuit device may overwrite data in memory cells connected to the four activated word lines. In FIG. 8, four word lines adjacent to each other are illustrated to be activated simultaneously. However, unlike this, at least some of the four word lines activated simultaneously may not be consecutive to each other. Since four word lines are activated simultaneously, the power consumption in the second normal refresh operation may be greater than the power consumption in the first normal refresh operation.

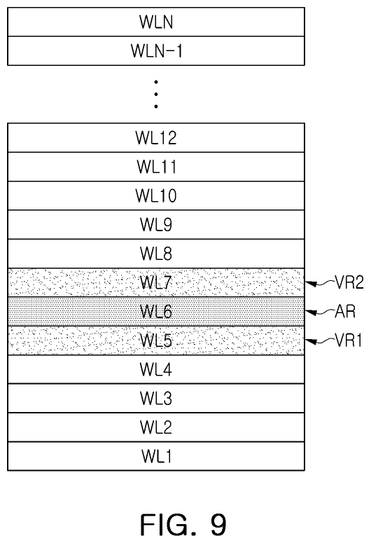

FIG. 9 may be a diagram for explaining a row hammer refresh operation. In the row hammer refresh operation according to the example embodiment illustrated in FIG. 9, a refresh operation may be executed on a pair of victim word lines VR1 and VR2 adjacent to the aggressor word line AR. The peripheral circuit area of the integrated circuit device may first control the row decoder connected to the word lines WL1 to WLN to activate the first victim word line VR1. Afterwards, data from memory cells connected to the first victim word line VR1 may be read and written again. Next, the peripheral circuit area may control the row decoder to activate the second victim word line VR2, read data from memory cells connected to the second victim word line VR2, and write it again. The first victim word line VR1 may be activated at the first refresh timing, and the second victim word line VR2 may be activated at the second refresh timing. The time between the first refresh timing and the second refresh timing may be defined as a refresh period. For example, the refresh period may be several microseconds.

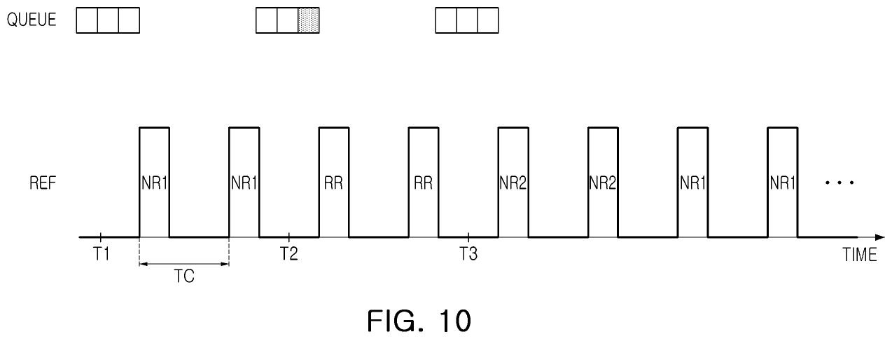

If the row hammer refresh operation is executed, the normal refresh operation may not be executed at the two refresh timings and may be skipped. Accordingly, at least one of the refresh timings that come after the row hammer refresh operation, the second normal refresh operation may be executed to compensate for the normal refresh operation skipped due to the row hammer refresh operation. Hereinafter, it will be described in more detail with reference to FIGS. 10 to 13.

FIGS. 10 to 13 are drawings illustrating the operation of an integrated circuit device according to example embodiments. FIG. 10 may be a diagram schematically illustrating the timing of a refresh operation of an integrated circuit device according to example embodiments. Referring to FIG. 10, a refresh operation may be executed in the integrated circuit device whenever a refresh timing arrives after the first time point T1. The refresh operation may be selected between a normal refresh operation and a row hammer refresh operation depending on whether the row hammer address is stored in the queue QUEUE.

The refresh timing occurs every predetermined refresh period TC, and the refresh period TC may vary depending on the retention characteristics of memory cells, the number of word lines included in the memory cell array, or the like. For example, the time that needs to be refreshed considering the retention characteristics of the memory cell may be defined as a refresh window time, and for example, may be 64 milliseconds. On the other hand, the refresh period TC may be determined according to the number of times word lines are activated for refresh during one refresh window time. The refresh period TC may vary depending on example embodiments, and may be, for example, 7.8 microseconds, 3.9 microseconds, or the like.

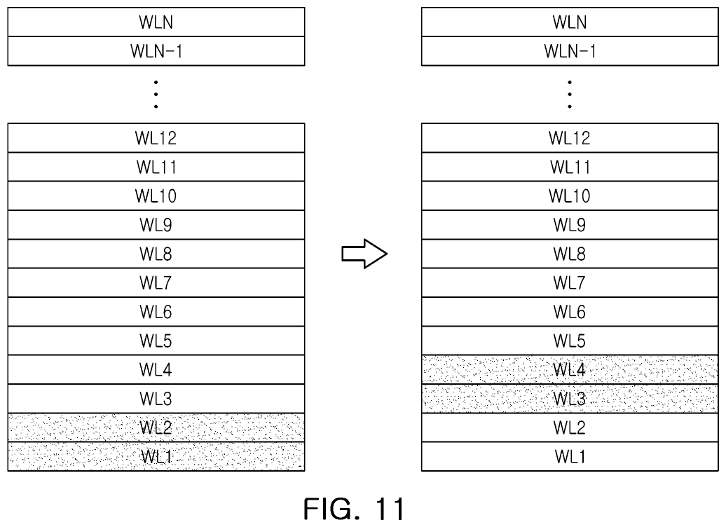

Referring to FIG. 10, at the first time point T1, there is no row hammer address stored in the queue QUEUE, and the logic circuit of the integrated circuit device may execute the first normal refresh operation NR1. Referring to FIG. 10 and FIG. 11 together, in the first normal refresh operation, the word lines WL1 to WLN may be activated by two at a time. Therefore, at the first refresh timing, memory cells connected to the first and second word lines WL1 to WL2 may be refreshed, and at the second refresh timing, memory cells connected to the third and fourth word lines WL3 to WL4 may be refreshed.

On the other hand, at the second time point T2, a row hammer address stored in the queue may be detected. Accordingly, at the refresh timing that comes after the second time point T2, the logic circuit of the integrated circuit device may perform the row hammer refresh operation RR instead of the first normal refresh operation NR1. As previously explained, in the row hammer refresh operation RR, the logic circuit may select a pair of victim word lines adjacent to the aggressor word line, one at a time.

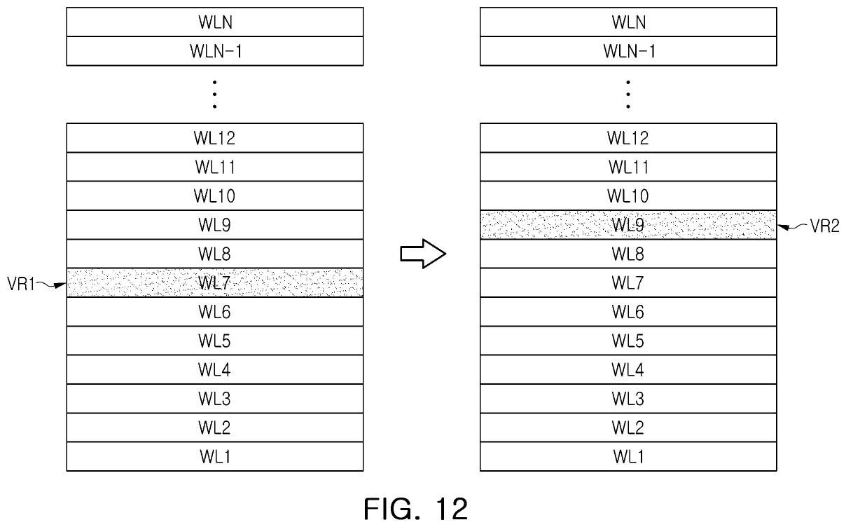

Referring to FIG. 12 illustrating an example of the row hammer refresh operation RR, the aggressor word line may be the eighth word line WL8. The logic circuit may refresh memory cells connected to the seventh word line WL7, which is the first victim word line VR1, at the third refresh timing. Additionally, the logic circuit may refresh memory cells connected to the ninth word line WL9, which is the second victim word line VR2, at the fourth refresh timing.

As the row hammer refresh operation RR is completed, as illustrated in FIG. 10, the row hammer address stored in the queue QUEUE may no longer exist from the third time point T3. On the other hand, since the first normal refresh operation NR1 is skipped to execute the row hammer refresh operation at the third and fourth refresh timings, to compensate therefor, the second normal refresh operation NR2 may be executed at the fifth and sixth refresh timings.

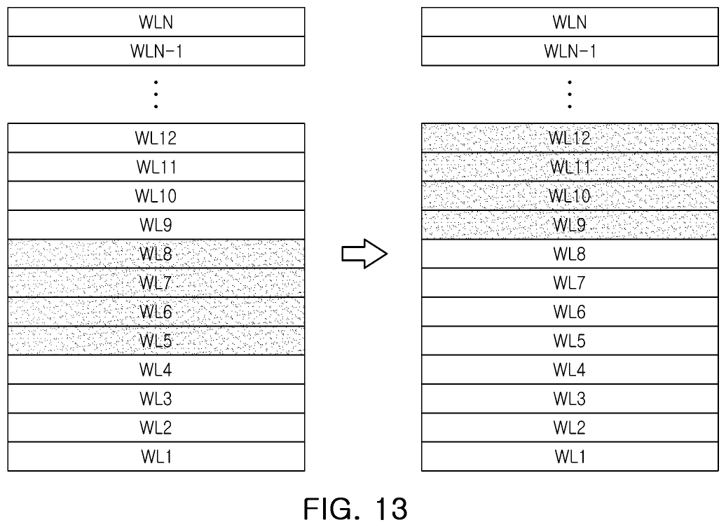

Referring to FIG. 12 along with FIG. 13, in the second normal refresh operation NR2, the word lines WL1 to WLN may be activated by four at a time. Since the refresh of the memory cells connected to the fourth word line WL4 was completed at the second refresh timing when the last normal refresh operation was executed, the logic circuit may refresh memory cells connected to the fifth to eighth word lines WL5 to WL8 at the fifth refresh timing. On the other hand, the logic circuit may refresh memory cells connected to the 9th to 12th word lines WL9 to WL12 at the sixth refresh timing.

In this manner, the row hammer refresh operation RR may be compensated by executing the second normal refresh operation NR2 at least once or more after the row hammer refresh operation RR. Assuming that in an example embodiment illustrated in FIG. 10, the row hammer refresh operation RR is not executed and the first normal refresh operation NR1 is executed in each of the first to sixth refresh timings, at the sixth refresh timing, memory cells connected to the 11th and 12th word lines WL11 to WL12 may be refreshed. Therefore, while executing the row hammer refresh operation RR to minimize data fluctuations due to the row hammer phenomenon, the refresh operation of memory cells connected to other word lines may also be guaranteed, and data loss in memory cells connected to other word lines may be effectively prevented.

When the row hammer refresh operation RR is compensated by executing the second normal refresh operation NR2, the first normal refresh operation NR1 may be executed again. As such, in example embodiments, the row hammer refresh operation RR, the first normal refresh operation NR1, and the second normal refresh operation NR2 may be dynamically scheduled based on whether the row hammer address is stored in the queue QUEUE. Therefore, data fluctuations due to the row hammer phenomenon and data loss due to omission of the refresh operation may be minimized, and power consumption may be reduced by executing the second normal refresh operation NR2 only as necessary.

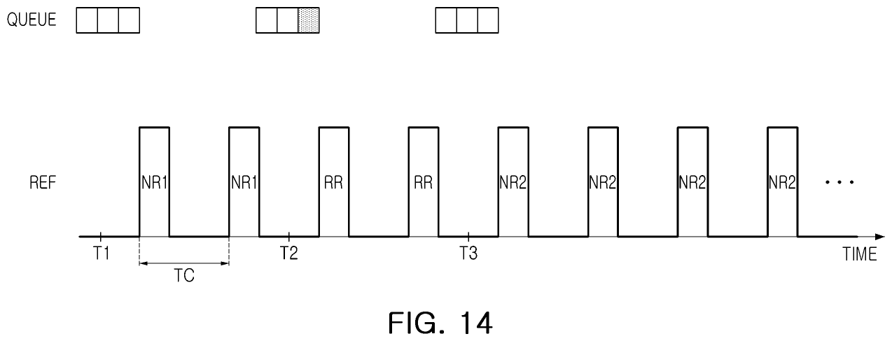

FIG. 14 is a diagram schematically illustrating the timing of a refresh operation of an integrated circuit device according to example embodiments. Referring to FIG. 14, a refresh operation may be executed in the integrated circuit device whenever a refresh timing arrives after the first time point T1. Similar to the example embodiment described with reference to FIG. 10, the row hammer address may be stored in the queue QUEUE at the second time point T2. Accordingly, the first normal refresh operation NR1 may be executed at each of the first and second refresh timings, and the row hammer refresh operation RR may be executed at each of the third and fourth refresh timings. The refresh period TC may be determined as previously described with reference to FIG. 10.

A second normal refresh operation NR2 may be executed at each of the fifth and sixth refresh timings, and this may be to make up for the normal refresh operation that was not executed at the third and fourth refresh timings to execute the row hammer refresh operation RR.

In the example embodiment illustrated in FIG. 14, the second normal refresh operation NR2 may be executed also at the sixth and seventh refresh timings. Therefore, power consumption may further increase compared to the example embodiment illustrated in FIG. 10. However, by increasing the number of executions of the second normal refresh operation NR2, the number of refreshes of memory cells connected to individual word lines may be increased and data stability may be improved.

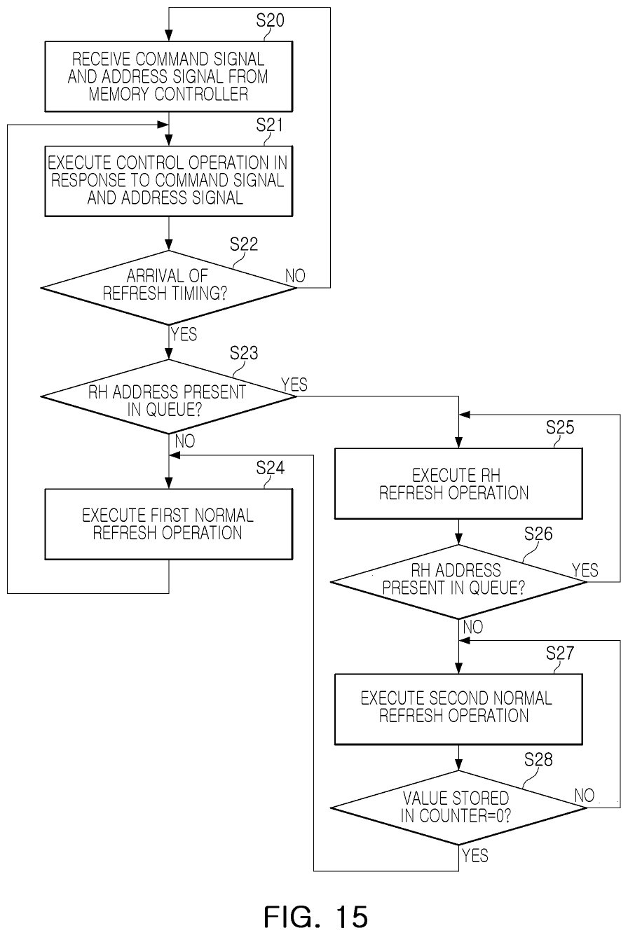

FIG. 15 is a flowchart illustrating the operation of an integrated circuit device according to example embodiments. Referring to FIG. 15, the operation of an integrated circuit device according to example embodiments may begin with the integrated circuit device receiving a command signal and an address signal from a memory controller (S20). The integrated circuit device may be a memory device storing data, and may execute control operations according to command signals and address signals (S21). The control operation may include a write operation to save data, a read operation to output the stored data to the memory controller, and a refresh operation to rewrite the stored data.

While executing the control operation, the logic circuit of the integrated circuit device may determine whether the refresh timing has arrived (S22). If it is determined that the refresh timing has not arrived, the logic circuit of the integrated circuit device may process control operations according to the command signal and address signal received from the memory controller (S20-S21). On the other hand, when it is determined that the refresh timing has arrived, the logic circuit may determine whether a row hammer address is present in a queue arranged in the peripheral circuit area (S23). The row hammer address may include at least one of the address of the aggressor word line that generates the row hammer phenomenon and the address of the victim word line adjacent to the aggressor word line.

As a result of the determination in operation S23, if the row hammer address is not present in the queue, the logic circuit may perform the first normal refresh operation (S24). In a first normal refresh operation, the logic circuit of the integrated circuit device may activate at least one of a plurality of word lines and perform a refresh operation of reading data from memory cells connected to the activated word line and writing it again. In example embodiments, in the first normal refresh operation, n word lines (n is a natural number of 2 or more) may be activated simultaneously at a time.

On the other hand, if the row hammer address is present in the queue as a result of the determination in operation S23, the logic circuit of the integrated circuit device may perform the row hammer RH refresh operation (S25). In the row hammer refresh operation, the logic circuit may refer to the row hammer address stored in the queue and specify the victim word line adjacent to the aggressor word line as the target word line. For example, the logic circuit of the integrated circuit device may specify a pair of victim word lines adjacent to the aggressor word line as target word lines.

In example embodiments, target word lines may be activated one at a time in a row hammer refresh operation. For example, the logic circuit of the integrated circuit device may activate a first victim word line adjacent to the aggressor word line at the first refresh timing and overwrite data in memory cells connected to the first victim word line. At the second refresh timing immediately after the first refresh timing, the logic circuit of the integrated circuit device may activate a second victim word line adjacent to the aggressor word line and overwrite data in memory cells connected to the second victim word line.

When the row hammer refresh operation is completed, the row hammer address stored in the queue before executing the row hammer refresh operation may be deleted from the queue. On the other hand, the logic circuit may determine whether a row hammer address remains in the queue (S26). Assuming that the first row hammer address and the second row hammer address are stored in the queue in operation S23, the first row hammer address may be deleted from the queue as the row hammer refresh operation is completed. Accordingly, the second row hammer address stored in the queue may be detected in operation S26.

If it is determined in operation S26 that the row hammer address is stored in the queue, the logic circuit may additionally perform a row hammer refresh operation (S25). On the other hand, if it is determined in operation S26 that there is no row hammer address stored in the queue, the logic circuit may perform a second normal refresh operation at the next refresh timing (S27). The second normal refresh operation is similar to the first normal refresh operation, but the number of word lines activated at one time in the second normal refresh operation may be greater than the number of word lines activated at one time in the first normal refresh operation.

For example, the logic circuit may activate m word lines (m is a natural number greater than n) at the same time in the second normal refresh operation. In this manner, by simultaneously activating a greater number of word lines in the second normal refresh operation than in the first normal refresh operation, the first normal refresh operation that is not executed at the first refresh timing and the second refresh timing may be compensated.

In an example embodiment described with reference to FIG. 15, the value stored in the counter included in the peripheral circuit area may increase by 1 each time the row hammer refresh operation is executed in operation S25. As explained earlier, the row hammer refresh operation is executed by activating a pair of victim word lines one by one, and thus, the value stored in the counter may increase by 1 under the condition that the row hammer refresh operation is executed while the refresh timing occurs twice.

The logic circuit of the integrated circuit device deducts the value stored in the counter by 1 each time the second normal refresh operation is executed twice in operation S27, and after the second normal refresh operation is executed, it may be determined whether the value stored in the counter is 0 (S28). As described above, in the second normal refresh operation, a greater number of word lines may be activated at once compared to the first normal refresh operation. For example, the number of word lines activated at once in the second normal refresh operation may be twice the number of word lines activated at once in the first normal refresh operation, and by executing the second normal refresh operation twice, the first normal refresh operation skipped due to the row hammer refresh operation may be compensated. Therefore, under the condition that the second normal refresh operation is executed while the refresh timing passes twice, the value stored in the counter may decrease by 1.

If the value stored in the counter is 0, the logic circuit may determine that all of the first normal refresh operations skipped to execute the row hammer refresh operation have been compensated. Therefore, the first normal refresh operation may be executed from the next refresh timing (S24). On the other hand, if the value stored in the counter is greater than 0, the second normal refresh operation may be further executed until the value stored in the counter becomes 0 (S27).

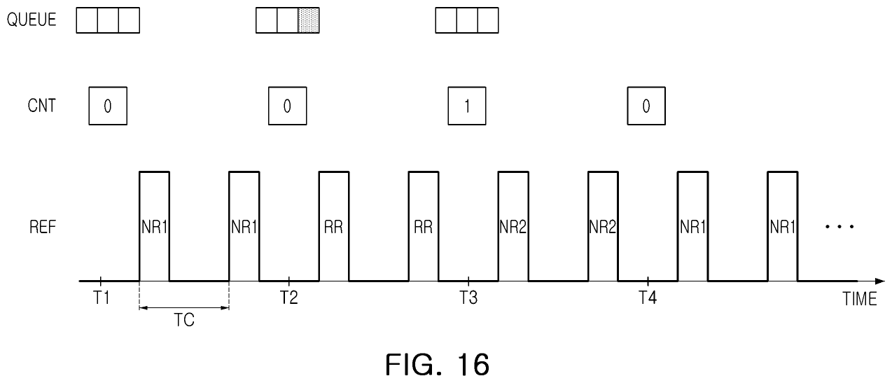

FIG. 16 is a diagram illustrating the operation of an integrated circuit device according to example embodiments.

Referring to FIG. 16, a refresh operation may be executed in the integrated circuit device whenever a refresh timing arrives at a predetermined refresh period TC after the first time point T1. The refresh operation may be selected between a normal refresh operation and a row hammer refresh operation depending on whether a row hammer address is stored in the queue QUEUE.

Similar to the example embodiment previously described with reference to FIG. 10, the row hammer address may be stored in the queue QUEUE at the second time point T2. Accordingly, the first normal refresh operation NR1 may be executed at each of the first and second refresh timings, and the row hammer refresh operation RR may be executed at each of the third and fourth refresh timings. Additionally, as the row hammer refresh operation RR is executed at each of the third and fourth refresh timings, the value stored in the counter CNT may increase from 0 to 1.

A second normal refresh operation NR2 may be executed at each of the fifth and sixth refresh timings, and this may be performed to compensate for the normal refresh operation that was not executed at the third and fourth refresh timings so that the row hammer refresh operation RR could be performed instead.

In example embodiments, the number of word lines activated at a time in the second normal refresh operation NR2 may be twice the number of word lines activated at a time in the first normal refresh operation NR1. Accordingly, the first normal refresh operation that was not executed at the third and fourth refresh timings may be compensated for by the second normal refresh operation NR2 executed at the fifth and sixth refresh timings, respectively.

At the fourth time point T4 after the sixth refresh timing, the value stored in the counter CNT may decrease back to 0. After the fourth time point T4, since the value stored in the counter CNT is 0 and there is no row hammer address stored in the queue QUEUE, the logic circuit of the integrated circuit device may again execute the first normal refresh operation NR1 at each refresh timing.

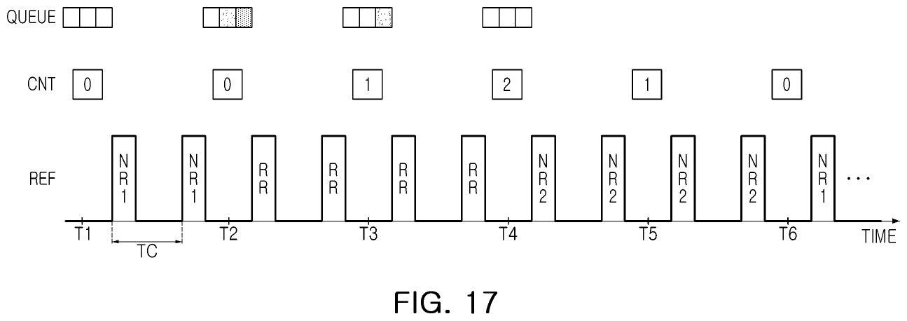

FIG. 17 is a diagram illustrating the operation of an integrated circuit device according to example embodiments. Referring to FIG. 17, a refresh operation may be executed in the integrated circuit device whenever a refresh timing arrives at a predetermined refresh period TC after the first time point T1. The refresh operation may be selected from the normal refresh operations NR1 and NR2 and the row hammer refresh operation RR depending on whether the row hammer address is stored in the queue QUEUE. Additionally, one of the first normal refresh operation NR1 and the second normal refresh operation NR2 may be selected according to the value stored in the counter CNT. The value stored in the counter CNT may be increased by the number of times the row hammer refresh operation RR is executed, and may be decreased by the number of times the second normal refresh operation NR2 is executed.

Referring to FIG. 17, the first row hammer address and the second row hammer address may be stored in the queue QUEUE at the second time point T2. Accordingly, the first normal refresh operation NR1 may be executed at each of the first and second refresh timings, and a row hammer refresh operation RR based on the first row hammer address may be executed at each of the third and fourth refresh timings. As the row hammer refresh operation RR is executed at each of the third and fourth refresh timings, the value stored in the counter CNT may increase to 1 at the third time point T3. On the other hand, at the third time point T3, the first row hammer address stored in the queue may be deleted.

A row hammer refresh operation RR based on the second row hammer address may be executed at each of the fifth and sixth refresh timings. At the fourth time point T4, after the sixth refresh timing has elapsed, the second row hammer address stored in the queue QUEUE may also be deleted. Additionally, since the row hammer refresh operation RR is executed in the third to sixth refresh timings, the value stored in the counter CNT may be set to 2 at the fourth time point T4.

The logic circuit of the integrated circuit device may execute a normal refresh operation instead of the row hammer refresh operation RR from the seventh refresh timing after the fourth time point T4, considering the condition that no row hammer address remains in the queue QUEUE. Additionally, the logic circuit may perform the second normal refresh operation NR2 until the value stored in the counter CNT becomes 0, and this may be to compensate for the first normal refresh operation NR1, which was skipped to execute the row hammer refresh operation RR in the third to sixth refresh timings.

Referring again to FIG. 17, after executing the second normal refresh operation NR2 at each of the seventh and eighth refresh timings, the value stored in the counter CNT at the fifth time point T5 may be deducted from 2 to 1. As described above, by executing the second normal refresh operation NR2 twice, the row hammer refresh operation RR for a pair of victim word lines adjacent to one aggressor word line may be compensated. Accordingly, by executing the second normal refresh operation NR2 at the seventh and eighth refresh timings, the row hammer refresh operation RR previously executed at the third and fourth refresh timings may be compensated, and the value stored in the counter CNT may be subtracted by 1.

Next, the second normal refresh operation NR2 may be executed at each of the ninth and tenth refresh timings, and the value stored in the counter CNT may be subtracted from 1 to 0. Therefore, at the sixth time point T6, since the value stored in the counter CNT is 0 and there is no row hammer address stored in the queue QUEUE, the logic circuit may perform the first normal refresh operation NR1 again.

Table 1 below may be a table illustrating word lines that are refreshed at each refresh timing in the example embodiment of FIG. 17 in which a row hammer occurs and in the case in which a row hammer does not occur. In Table 1, the first and second victim word lines VR1 and VR2 are word lines adjacent to the aggressor word line of the first row hammer address, and the third and fourth victim word lines VR3 and VR4 may be word lines adjacent to the aggressor word line of the second row hammer address.

In the first normal refresh operation NR1, two word lines may be activated at a time, and in the second normal refresh operation NR2, four word lines may be activated at a time. As illustrated in Table 1, by determining the number of execution times of the second normal refresh operation NR2 based on the value stored in the counter CNT, the first normal refresh operation NR1 that is skipped due to the row hammer refresh operation RR may be compensated. Additionally, by limiting the number of executions of the second normal refresh operation NR2 to the necessary number, power consumption in the refresh operation may be efficiently managed.

TABLE 1

| | Occurrence | Non-occurrence |
|---|---|---|
| Refresh | of Row | of Row |
| Timing | Hammer (FIG. 17) | Hammer |
| 1st | WL1, WL2 | WL1, WL2 |
| 2nd | WL3, WL4 | WL3, WL4 |
| 3rd | VR1 | WL5, WL6 |
| 4th | VR2 | WL7, WL8 |
| 5th | VR3 | WL9, WL10 |
| 6th | VR4 | WL11, WL12 |
| 7th | WL5-WL8 | WL13, WL14 |
| 8th | WL9-WL12 | WL15, WL16 |
| 9th | WL13-WL16 | WL17, WL18 |
| 10th | WL17-WL20 | WL19, WL20 |
| 11th | WL21, WL22 | WL21, WL22 |

Thus, as shown by FIG. 17, the first normal refresh operation NR1 may be executed under the condition that the value stored in the counter CNT is 0 and the queue QUEUE is empty. On the other hand, the second normal refresh operation NR2 may be executed under the condition that the value stored in the counter CNT is greater than 0.

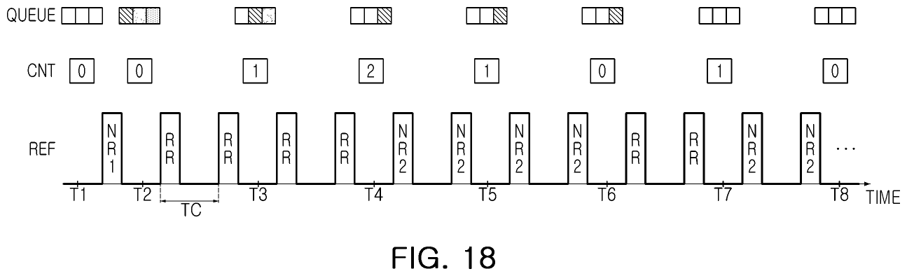

FIG. 18 is a diagram illustrating the operation of an integrated circuit device according to example embodiments. Referring to FIG. 18, a refresh operation may be executed in the integrated circuit device whenever a refresh timing arrives at a predetermined refresh period TC after the first time point T1. The refresh operation may be selected from the normal refresh operations NR1 and NR2 and the row hammer refresh operation RR depending on whether the row hammer address is stored in the queue QUEUE. Additionally, one of the first normal refresh operation NR1 and the second normal refresh operation NR2 may be selected according to the value stored in the counter CNT. The value stored in the counter CNT may be increased by the number of times the row hammer refresh operation RR is executed, and may be decreased by the number of times the second normal refresh operation NR2 is executed.

Referring to FIG. 18, at a second time point T2, the first row hammer address, the second row hammer address, and the third row hammer address may be stored in the queue QUEUE in that order. Accordingly, the first normal refresh operation NR1 may be executed at the first refresh timing, and the row hammer refresh operation RR based on the first row hammer address may be executed at each of the second and third refresh timings. As the row hammer refresh operation RR is executed at each of the second and third refresh timings, the value stored in the counter CNT may increase to 1 at the third time point T3. On the other hand, the first row hammer address stored in the queue QUEUE may be deleted at the third time point T3.

A row hammer refresh operation RR based on the second row hammer address may be executed at each of the fourth and fifth refresh timings. At the fourth time point T4, after the fifth refresh timing has elapsed, the second row hammer address stored in the queue QUEUE may also be deleted. Additionally, since the row hammer refresh operation RR is executed in the second to fifth refresh timings, the value stored in the counter CNT may be set to 2 at the fourth time point T4.

In an example embodiment illustrated in FIG. 18, when the value stored in the counter CNT reaches a predetermined reference value, the logic circuit of the integrated circuit device may perform a normal refresh operation regardless of whether the row hammer address is stored in the queue QUEUE. Like the example embodiment previously described with reference to FIG. 17, in the example embodiment illustrated in FIG. 18, the value stored in the counter CNT may increase by 1 according to the number of executions of the row hammer refresh operation RR and may decrease by 1 according to the number of executions of the second normal refresh operation NR2. Accordingly, the fact that the value stored in the counter CNT reaches a predetermined reference value may indicate that the number of consecutive executions of the row hammer refresh operation RR has reached the predetermined reference number.

When the number of consecutive executions of the row hammer refresh operation RR reaches the reference number, for example, and when the value stored in the counter CNT reaches a predetermined reference value, the logic circuit may execute the second normal refresh operation NR2 regardless of the state of the queue QUEUE. For example, the second normal refresh operation NR2 may be continuously executed until the value stored in the counter CNT becomes 0. In detail, the logic circuit may continuously execute the second normal refresh operation NR2 as many times as the row hammer refresh operation RR is continuously executed.

Referring still to FIG. 18, despite the third row hammer address being stored in the queue QUEUE at the fourth time point T4, the logic circuit may execute the second normal refresh operation NR2 instead of the row hammer refresh operation RR starting from the sixth refresh timing. As illustrated in FIG. 18, the second normal refresh operation NR2 may be continuously executed as many times as the row hammer refresh operation RR has been continuously executed. The second normal refresh operation NR2 is executed as many times as the row hammer refresh operation RR is continuously executed, so that the value stored in the counter CNT may decrease to 0 at the sixth time point T6.

When the value stored in the counter CNT decreases to 0, the logic circuit may again refer to the third row hammer address stored in the queue QUEUE and execute the row hammer address operation RR. The row hammer address operation RR is executed at the tenth and eleventh refresh timings after the sixth time point T6, which may cause the value stored in the counter CNT to increase back to 1 at the seventh time point T7. Accordingly, at the twelfth and thirteenth refresh timings, the logic circuit may perform the second normal refresh operation NR2. As the second normal refresh operation NR2 is executed at the twelfth and thirteenth refresh timings, the value stored in the counter CNT may decrease back to 0 at the eighth time point T8.

When comparing the refresh operation described with reference to FIG. 18 to the case where no row hammer occurs, the results may be as illustrated in Table 2 below. In Table 2, the first and second victim word lines VR1 and VR2 may be word lines adjacent to the aggressor word line of the first row hammer address, and the third and fourth victim word lines VR3 and VR4 may be word lines adjacent to the aggressor word line of the second row hammer address. The fifth and sixth victim word lines VR5 and VR6 may be word lines adjacent to the aggressor word line of the third row hammer address. On the other hand, two word lines may be activated at a time in the first normal refresh operation NR1, and four word lines may be activated at a time in the second normal refresh operation NR2.

TABLE 2

| | Occurrence | Non-occurrence |
|---|---|---|
| Refresh | of Row | of Row |
| Timing | Hammer (FIG. 18) | Hammer |
| 1st | WL1, WL2 | WL1, WL2 |
| 2nd | VR1 | WL3, WL4 |
| 3rd | VR2 | WL5, WL6 |
| 4th | VR3 | WL7, WL8 |
| 5th | VR4 | WL9, WL10 |
| 6th | WL3-WL6 | WL11, WL12 |
| 7th | WL7-WL10 | WL13, WL14 |
| 8th | WL11-WL14 | WL15, WL16 |
| 9th | WL15-WL18 | WL17, WL18 |
| 10th | VR5 | WL19, WL20 |
| 11th | VR6 | WL21, WL22 |
| 12th | WL19-WL22 | WL23, WL24 |
| 13th | WL23-WL26 | WL25, WL26 |

Referring again to FIG. 18, the first normal refresh operation NR1 may be executed under the condition that the value stored in the counter CNT is 0 and the row hammer address is not stored in the queue QUEUE. On the other hand, the second normal refresh operation NR2 may be executed under the condition that the value stored in the counter CNT is greater than 0.

In various embodiments of the present inventive concept, power consumption and refresh operation performance may be improved by dynamically scheduling a refresh operation executed in an integrated circuit device. For example, when a row hammer occurs and the row hammer address is stored in the queue, data fluctuations in memory cells connected to the victim word line may be minimized by executing the row hammer refresh operation instead of the normal refresh operation at the refresh timing.

In example embodiments, the number of execution times of the row hammer refresh operation may be stored in a counter, and the refresh operation may be scheduled based thereon. For example, when a row hammer refresh operation is executed, the value stored in the counter may increase by 1, and when the second normal refresh operation is executed to compensate for the first normal refresh operation skipped due to the row hammer refresh operation, the value stored in the counter may decrease by 1. As described above, the value stored in the counter may increase by 1 when the row hammer refresh operation is executed in two consecutive refresh timings, and may decrease by 1 when the second normal refresh operation is executed in two consecutive refresh timings.

In example embodiments, when the value stored in the counter reaches a predetermined reference value, a second normal refresh operation may be executed regardless of whether a row hammer address is stored in the queue, and this may be to prevent data reliability problems that may occur if a normal refresh operation(s) is skipped too many times over a relatively long time interval. When the value stored in the counter reaches a predetermined reference value, the second normal refresh operation may be executed until the value stored in the counter decreases to another reference value, and then the row hammer refresh operation or the first normal refresh operation may be executed again.

As set forth above, according to example embodiments, a normal refresh operation may be executed at every predetermined cycle, and a row hammer refresh operation may be executed under the condition that a row hammer address stored in a queue is present. Accordingly, the effect of the refresh operation may be improved by preventing the row hammer refresh operation from being unnecessarily executed under conditions in which the row hammer phenomenon is not detected. In addition, by counting the number of times the row hammer refresh operation has been executed in a row and scheduling the normal refresh operation and the row hammer refresh operation based thereon, power consumed in the refresh operation may be reduced and defense against row hammer may be effectively secured.

While example embodiments have been illustrated and described above, it will be apparent to those skilled in the art that modifications and variations could be made without departing from the scope of the present inventive concept as defined by the appended claims.

What is claimed is:

1. A semiconductor device, comprising:
a cell area in which a plurality of memory banks are disposed, each of the plurality of memory banks including a respective memory cell array including a plurality of memory cells,
a row decoder connected to the memory cell array through a plurality of word lines; and
a sense amplifier circuit connected to the memory cell array through a plurality of bit lines; and
a peripheral circuit area in which a logic circuit controlling the plurality of memory banks is disposed; and
wherein the logic circuit includes at least one queue configured to store a row hammer address for at least one of the plurality of memory banks, and configured to control a target memory bank to execute a row hammer refresh operation in the target memory bank indicated by a row hammer address when the row hammer address stored in the queue is present, and control the plurality of memory banks to execute a normal refresh operation when the row hammer address stored in the queue is not present.

2. The semiconductor device of claim 1,
wherein the normal refresh operation includes a first normal refresh operation and a second normal refresh operation;
wherein the logic circuit is configured to activate the plurality of word lines by an n number at a time during the first normal refresh operation, and activate the plurality of word lines by an m number at a time during the second normal refresh operation; and
wherein each of the m and the n is a natural number of 2 or more, and n is smaller than m.

3. The semiconductor device of claim 2, wherein the logic circuit is configured to execute the second normal refresh operation at a refresh timing immediately following the row hammer refresh operation.

4. The semiconductor device of claim 3, wherein the logic circuit is configured to execute the second normal refresh operation twice in a row immediately after the row hammer refresh operation.

5. The semiconductor device of claim 1, wherein the logic circuit includes a plurality of queues corresponding to the plurality of memory banks; and wherein a number of the plurality of memory banks is equal to a number of the plurality of queues.

6. The semiconductor device of claim 1, wherein the logic circuit includes a counter configured to store a number of times the row hammer refresh operation has been continuously executed for at least one of the plurality of memory banks; and wherein when the number of times stored in the counter reaches a predetermined reference number, the logic circuit continuously executes the normal refresh operation by the predetermined reference number.

7. The semiconductor device of claim 6, wherein the logic circuit includes a plurality of counters corresponding to the plurality of memory banks; and wherein a number of the plurality of memory banks is equal to a number of the plurality of counters.

8. The semiconductor device of claim 6, wherein the logic circuit is configured to execute a first normal refresh operation of activating the plurality of word lines by an n number at a time, at a refresh timing before the row hammer refresh operation; wherein when the number of times stored in the counter reaches a predetermined reference number, the logic circuit continuously executes a second normal refresh operation of activating the plurality of word lines by an m number at a time, by the predetermined reference number; and wherein the m number is greater than the n number.

9. A semiconductor device, comprising:
a cell area in which a plurality of memory banks are disposed, each of the plurality of memory banks including: a memory cell array including a plurality of memory cells, a row decoder connected to the memory cell array through a plurality of word lines, and a sense amplifier circuit connected to the memory cell array through a plurality of bit lines; and
a peripheral circuit area configured to execute, for each of the plurality of memory banks, a row hammer refresh operation in response to detecting an aggressor word line among the plurality of word lines by refreshing target memory cells connected to target word lines adjacent to the aggressor word line, a first normal refresh operation of activating the plurality of word lines by an n number at a time, and a second normal refresh operation of activating the plurality of word lines by an m number at a time, with the m number being more than the n number;
wherein the peripheral circuit area includes a counter storing a number of execution times of the row hammer refresh operation; and
wherein when the number of execution times stored in the counter is greater than 0, the peripheral circuit area executes the second normal refresh operation until the number of the execution times stored in the counter becomes 0.

10. The semiconductor device of claim 9, wherein n is 2 and m is 4.

11. The semiconductor device of claim 9, wherein the peripheral circuit area is configured to execute, for each of the plurality of memory banks, one of the row hammer refresh operation, the first normal refresh operation, and the second normal refresh operation when a refresh timing reaches at a predetermined refresh cycle.

12. The semiconductor device of claim 11, wherein when a number of the consecutive executions of the row hammer refresh operation reaches a predetermined reference number, the peripheral circuit area executes the second normal refresh operation by the number of consecutive executions of the row hammer refresh operation.

13. The semiconductor device of claim 11, wherein, within a refresh window time including the refresh timing by a predetermined number, a number of executions of the row hammer refresh operation is equal to a number of executions of the second normal refresh operation.

14. The semiconductor device of claim 11, wherein, within a refresh window time including the refresh timing by a predetermined number, a number of executions of the row hammer refresh operation is less than a number of executions of the second normal refresh operation.

15. The semiconductor device of claim 9, wherein the peripheral circuit area includes a queue storing a row hammer address, which is an address of the aggressor word line, and executes the row hammer refresh operation when the row hammer address stored in the queue is present.

16. A semiconductor device, comprising:
a cell area in which a plurality of memory banks are disposed, each of the plurality of memory banks including a plurality of memory cells connected to a plurality of word lines and a plurality of bit lines; and
a peripheral circuit area including a logic circuit configured to execute, for each of the plurality of memory banks, a row hammer refresh operation that detects an aggressor word line among the plurality of word lines and refreshes memory cells connected to victim word lines adjacent to the aggressor word line, and a normal refresh operation that refreshes memory cells connected to at least one selected word line among the plurality of word lines;
wherein the peripheral circuit area includes a queue in which a row hammer address indicating at least one of the aggressor word line and the victim word lines is stored, and a counter in which a number of executions of the row hammer refresh operation is stored; and
wherein the logic circuit is further configured to execute one of the row hammer refresh operation and the normal refresh operation at each refresh timing coming at a predetermined refresh period, based on at least one of a state of the queue and a value stored in the counter.

17. The semiconductor device of claim 16, wherein the logic circuit is configured to execute the row hammer refresh operation when the refresh timing arrives while the row hammer address is stored in the queue.

18. The semiconductor device of claim 16, wherein the logic circuit is configured to execute the normal refresh operation when the value stored in the counter is equal to a predetermined reference value.

19. The semiconductor device of claim 18, wherein the logic circuit is configured to execute the normal refresh operation regardless of the state of the queue when the value stored in the counter is equal to a predetermined reference value.

20. The semiconductor device of claim 16, wherein the normal refresh operation includes a first normal refresh operation that includes activating n word lines at a time, and a second normal refresh operation that includes activating m word lines, m being more than n; and wherein the logic circuit is configured to execute the first normal refresh operation when the queue is empty and the value stored in the counter is 0, and execute the second normal refresh operation when the value stored in the counter is greater than 0.
